(19) United States
(12) Patent Application Publication
(10) Pub. No.: US 2002/0072164 A1
(43) Pub. Date: Jun. 13, 2002

(54) Processing chamber with multi-layer brazed lid

(75) Inventors: Sal Umotoy, Antioch, CA (US); Be Van Vo, Santa Clara, CA (US); Son Ngoc Trinh, Cupertino, CA (US)

Correspondence Address: Patent Counsel, MS/2061, Legal Affairs Dept., Applied Materials, Inc., P.O. Box 450A, Santa Clara, CA, 95052, US

(73) Assignee: APPLIED MATERIALS, INC., Santa Clara, CA (US)

(21) Appl. No.: 09/954,629

(22) Filed: Sep. 12, 2001

Related U.S. Application Data
(60) Provisional application No. 60/232,289, filed on Sep. 13, 2000.

(51) Int. Cl. H01L 21/8238

(52) U.S. Cl. 438/200

(57) ABSTRACT

In one embodiment of the present invention, an integral lid assembly (10) for sealing a substrate processing chamber includes first (16) and third (12) plates fixedly fused to a second plate (14) positioned therebetween. The first and second plates define a coolant passage (110) or channel therein, and the second and third plates define a gas delivery channel(s) (146, 148) therein. The first plate has a substantially planar surface for coupling to a processing chamber, and the third plate has a substantially planar surface for coupling to a microwave generation device or a remote plasma clean device (106). In this manner, the lid assembly is compact in size, and facilitates the mounting of a microwave device closer to the chamber than for bulkier lid assemblies. In another embodiment, gas passages (232) through the brazed lid assembly (200) are coupled to the processing chamber (310), and are configured to provide the desired gas distribution thereto for exemplary processes.

### CROSS-REFERENCE TO RELATED APPLICATIONS

This application claims the benefit of U.S. Provisional Application No. 60/232,289, entitled Processing Chamber With Multi-Layer Brazed Lid, filed Sep. 13, 2000, the complete disclosure of which is incorporated herein by reference.

### BACKGROUND OF THE INVENTION

The present invention relates to the fabrication of integrated circuits. More particularly, the invention provides methods and apparatus for controlling the temperature, maintaining the vacuum integrity and facilitating maintenance of a lid assembly for a semiconductor processing chamber.

High density integrated circuits, commonly termed VLSI devices, are typically formed on semiconductor wafers by subjecting the wafers to a number of deposition, masking, doping and etching processes. The wafers are placed on the upper surface of a pedestal or susceptor within a processing chamber, and process gas(es), such as tungsten hexafluoride and silane, are delivered into the chamber to perform the various deposition steps on the wafer. Typically, the process gases are directed through a manifold and mixed in a water-cooled gas mixing chamber within the manifold head. This cooling is often desired because the process gases may react to form a solid precipitate that deposits onto the walls of the manifold head at temperatures greater than a threshold temperature. After mixing in the cooled manifold head, the gaseous mixture is delivered through a lid assembly that includes one or more gas distribution plates for delivering a uniform distribution of the gaseous mixture into the deposition chamber and onto the wafer.

During processing, the gas distribution plates of the lid assembly (i.e., the gas distribution plate or showerhead and the gas dispersion plate or blocker plate) receive heat from the heated pedestal and the heated wafer in the processing chamber. Hence, the gas distribution plates heat the gases flowing therethrough. If these plates reach a threshold temperature, the process gases passing through the gas distribution system may react and deposit, clogging the gas distribution holes of the plates. In addition, a layer of deposition may form on the inner and/or outer surface of the plates to later flake off in large particulates that rain down on the wafer to create an uneven deposition layer, thereby contaminating the wafer.

The gas distribution plates of the lid assembly are typically mechanically coupled to a gas injection cover plate and a mounting plate, which are attached to a base plate for mounting to the processing chamber. The interfaces between these components are usually sealed with gas seals (e.g., O-rings) so as to maintain a vacuum-tight seal throughout the lid assembly. During installation of the lid assembly, however, it is often difficult to precisely align the gas seals within the corresponding grooves of the plates. In addition, the gas seal surfaces and grooves can be damaged from handling during this installation. A gas seal that has not been precisely installed or one that has been damaged during installation may cause a leak. This leak allows gas to pass through the lid assembly during processing, thereby disrupting the desired pressure within the processing chamber. Disruption of this desired pressure, which is typically on the order of 1-2 milliTorr, will adversely affect the deposition uniformity on the semiconductor wafer. Further, a leak may allow unwanted ambient air to enter the system, causing poor film deposition quality, such as a hazed film. Therefore, the gas seals must be repaired or reinstalled, or the entire lid assembly must be replaced when the vacuum integrity of its components has been compromised. Frequent reinstallation, repair or replacement of the lid assembly increases the manufacturing cost of the wafers and the downtime of the processing apparatus, which decreases the throughput of the process and further increases the manufacturing cost of the wafers.

What is needed in the semiconductor manufacturing industry, therefore, is an improved lid assembly for a wafer processing apparatus. It is desirable to provide a lid assembly of compact design to facilitate the use of a microwave generation source and/or a remote plasma clean assembly closely coupled to the lid assembly. It is further desirable to provide accurate temperature control and cooling of the lid assembly, and to provide even distribution of process gases, among other benefits.

### SUMMARY OF THE INVENTION

The present invention provides an exemplary lid assembly apparatus which is compact in design, provides low cost for assembly and ease of serviceability, and permits mounting of a microwave source or remote plasma clean unit directly on top of the lid assembly to give improved performance for plasma clean related processes. The present invention further provides methods of forming integrated circuits and operating semiconductor process chambers having lid assemblies of the present invention, including use of lid assemblies for exemplary process and/or inert gas distribution.

Lid assemblies of the present invention may be used for 200 mm, 300 mm and the like wafer processing apparatus. In one embodiment, the lid assembly includes three plates, preferably aluminum plates, which are brazed or fused together to form a fully integrated lid assembly. A different number of plates, such as two plates, four plates, or more, also may be used according to the present invention. The lid assembly includes gas lines and coolant channels formed therein. As a result, the present invention obviates the need for the use of quartz gas delivery tubes running over current lid assemblies.

In one embodiment of the present invention, an integral lid assembly for sealing a substrate processing chamber includes first and third plates fixedly coupled to a second plate positioned therebetween. In one aspect, the plates are brazed or fused together. The first and second plates define a fluid channel therein, and the second and third plates define a gas delivery channel therein. The fluid channel may be for heating or cooling fluids. The first plate has a substantially planar surface for coupling to the processing chamber, and the third plate has a substantially planar surface. In this manner, the lid assembly is compact in size, and the third plate substantially planar surface facilitates the mounting of a microwave or remote plasma clean device closer to the chamber than for bulkier lid assemblies.

In another embodiment, a lid assembly includes a multi-layer brazed plate formed of two or more individual plates. The brazed plate has substantially planar upper and lower surfaces. A coolant channel and a gas channel are each formed in opposing mated surfaces of individual plates making up the brazed plate.

In one aspect, the coolant and/or gas channel(s) are formed in a first plate surface, that is mated to a generally planar portion of a second plate surface. In such an embodiment, the channel(s) may have a generally semi-circular, or similar shaped cross-section. In another aspect, the coolant and/or gas channel(s) are formed in two opposing plate surfaces that are mounted together. In such an embodiment, the channel(s) may have a circular or similar cross-section, though need not.

In one embodiment, the substrate processing chamber further includes a microwave generator or remote plasma clean assembly mounted to the third plate substantially planar upper surface. In another embodiment, the processing chamber further includes a gas distribution plate removably mounted to the first plate. The gas distribution plate defines one or more gas distribution holes formed therethrough to communicate with the chamber.

In another embodiment, a lid assembly according to the present invention includes a first plate having first and second spaced apart surfaces defining a thickness therebetween. The second surface has a channel, such as a serpentine channel, formed therein and coupled to an inlet and an outlet. A second plate is coupled to the second surface. A third plate, having a first channel formed therein, is coupled to the second plate to fluidly seal the first channel.

In one aspect, the channel inlet and outlet are coupled to a fluid source, which may be a cooling or heating fluid source. In another aspect, the first channel is coupled to a gas source. In still another aspect, a second channel is formed in the third plate. The second channel is at least partially spaced apart from the first channel. In this manner, two different gases can be pass through the separate channels en route to the processing chamber.

In one aspect, the first and second plates each have a hole passing therethrough, with the holes aligned with one another and aligned with the third plate first channel outlet. In this manner, gas can be delivered from the first channel, through the first and second plates and to the processing chamber. In one aspect, a gas dispersion plate and/or a gas distribution plate is removably coupled to the lid assembly, such as to the first plate.

In one embodiment of the present invention, a substrate processing chamber lid assembly includes a multi-layer brazed plate formed of two or more individual plates. The multi-layer brazed plate includes a plurality of spaced apart gas injection ports configured to deliver gases to a processing chamber, a plurality of gas channels, each coupled to at least one of the injection ports, and a channel formed within the brazed plate and configured to be coupled to a fluid source. The fluid source may contain a cooling or heating fluid.

In one aspect, the gas injection ports are spaced about a surface of the brazed plate in a configuration designed to distribute gases therefrom in a desired pattern. In another aspect, at least one of the gas channels is coupled to a purge gas source, and at least another one of the gas channels is coupled to a process gas source.

Other objects, features and advantages of the present invention will become more fully apparent from the following detailed description, the appended claims and the accompanying drawings.

### BRIEF DESCRIPTION OF THE DRAWINGS

FIGS. 1A and 1B depict upper and lower perspective views, respectively, of a lid assembly of the present invention;

FIG. 1C is an exploded view of a lid assembly, gas distribution plate and gas dispersion plate according to the present invention;

FIG. 2 depicts an exploded, simplified cross-sectional view of the lid assembly depicted in FIG. 1;

FIGS. 3A and 3B depict a top view and a cross-sectional side view, respectively, of an assembled lid assembly according to the present invention;

FIGS. 4A-4C depict top, bottom and cross-sectional side views, respectively, of the lower component of a lid assembly of the present invention;

FIGS. 5A-5C depict top, bottom and cross-sectional side views, respectively, of the middle component of a lid assembly of the present invention;

FIGS. 6A-6C depict top, bottom and cross-sectional side views, respectively, of the upper component of a lid assembly of the present invention;

FIG. 7 depicts a simplified schematic of a substrate processing apparatus having a lid assembly according to the present invention;

FIG. 8 is a simplified cross section al view of another lid assembly embodiment according to the present invention;

FIG. 9 is a process schematic representation using a lid assembly of the present invention;

FIG. 10A is a simplified overall view of a lid assembly having multiple gas injection locations according to the present invention; and

FIG. 10B is a simplified overall exploded view of a lid assembly according to another embodiment of the present invention showing alternative configurations of gas distribution channels.

### DESCRIPTION OF THE SPECIFIC EMBODIMENTS

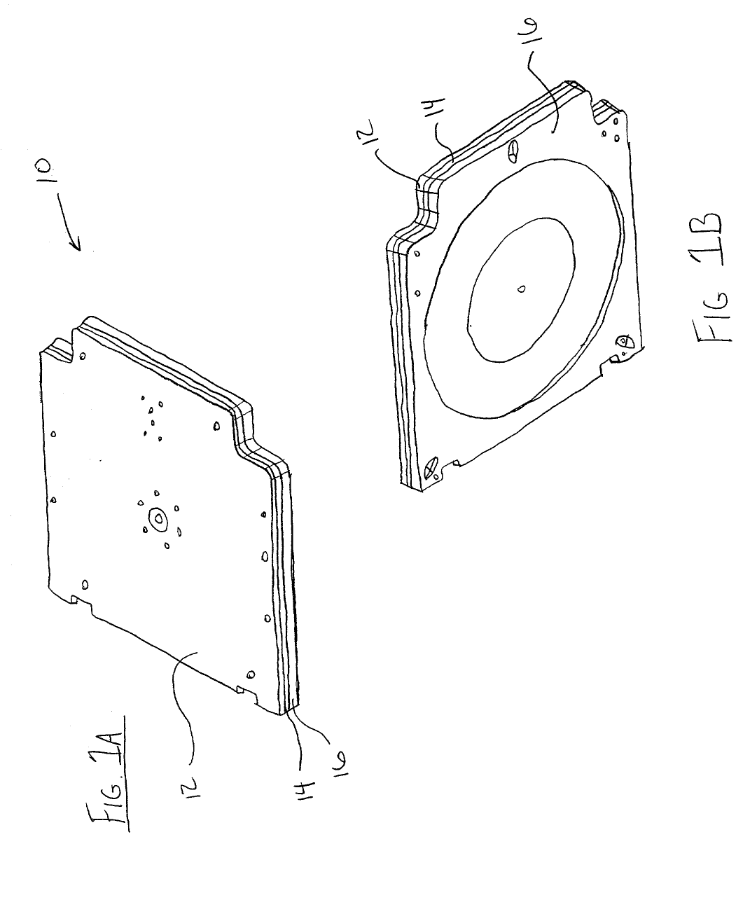

FIGS. 1A-1B depict an overview of a lid assembly 10 according to one embodiment of the present invention. As shown, lid assembly 10 includes three components which are fused or vacuum brazed together, to become a single assembly. A top or upper component or plate 12 and a middle component or plate 14 are fused together to form one or more gas lines therein. In one embodiment, two gas lines are formed, although a different number of lines may be formed within the scope of the present invention.

A bottom or lower component or plate 16 is vacuum brazed or fused to middle component 14 to form coolant channels therein. It will be appreciated by those skilled in the art that use of the terms top, upper, middle, bottom and lower are not intended to limit the scope of the present invention. For example, the top and lower components may be reversed, or the three components may be coupled in a left to right, right to left configuration, or in other configurations. Additional details on particular embodiments of lid assembly 10, and components thereof, are provided in conjunction with later figures.

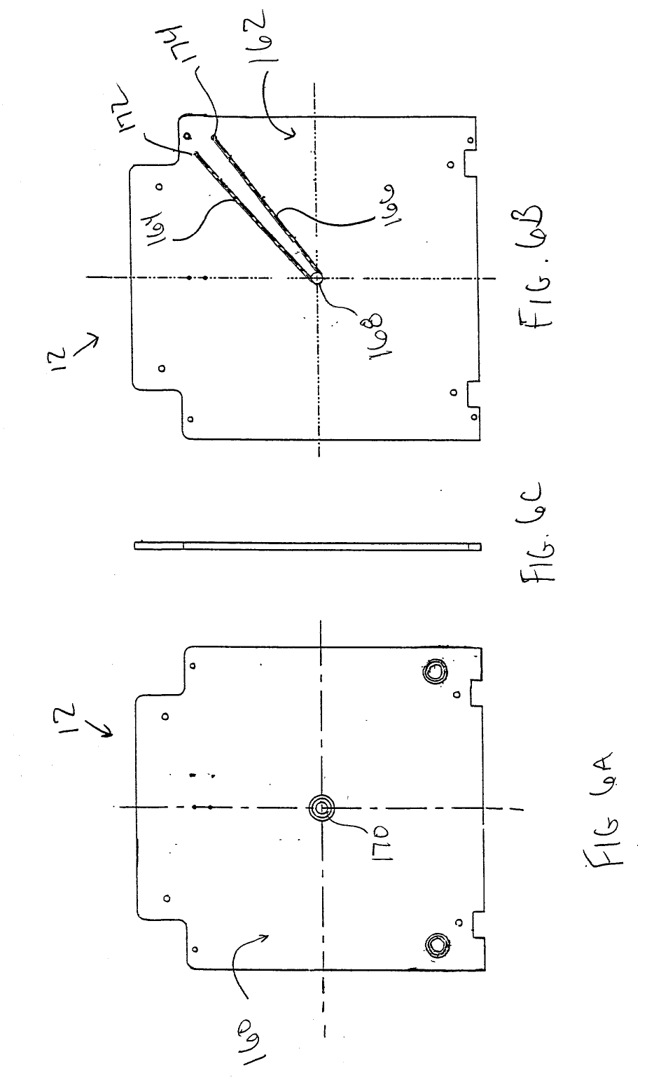

The lower side of lid assembly 10 is adapted to mount to a blocker plate and a showerhead as shown in FIG. 1C. Lid assembly 10, blocker plate and showerhead are mounted to a substrate process chamber as shown schematically in FIG. 7. The uppermost side of lid assembly 10 is generally flat, which facilitates the mounting of a microwave and applicator with a VAT™ gate valve for microwave isolation. VAT™ valves can be obtained from VAT Incorporated, having a United States office in Woburn, Mass. In another embodiment, the generally flat upper side of lid assembly 10 is coupled to a remote plasma clean assembly, such as a unit commercially available from Advanced Energy Industries Inc., headquartered in Fort Collins, Colorado.

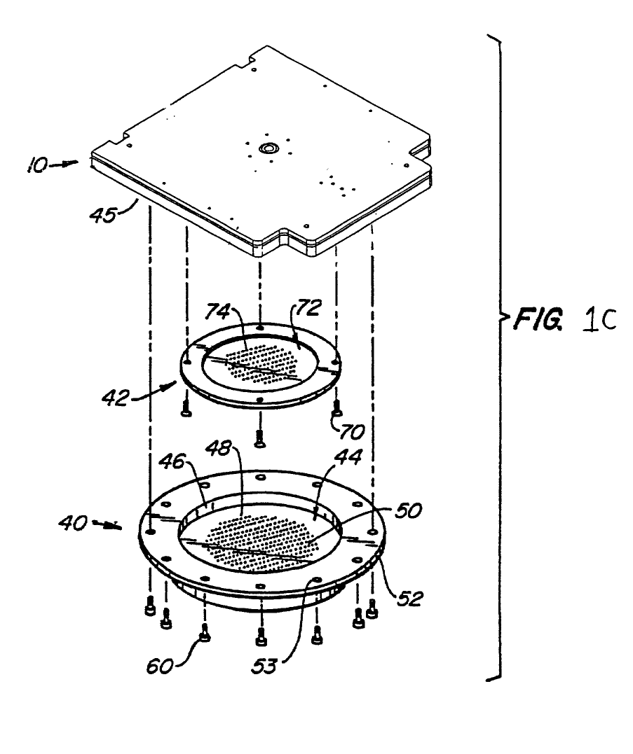

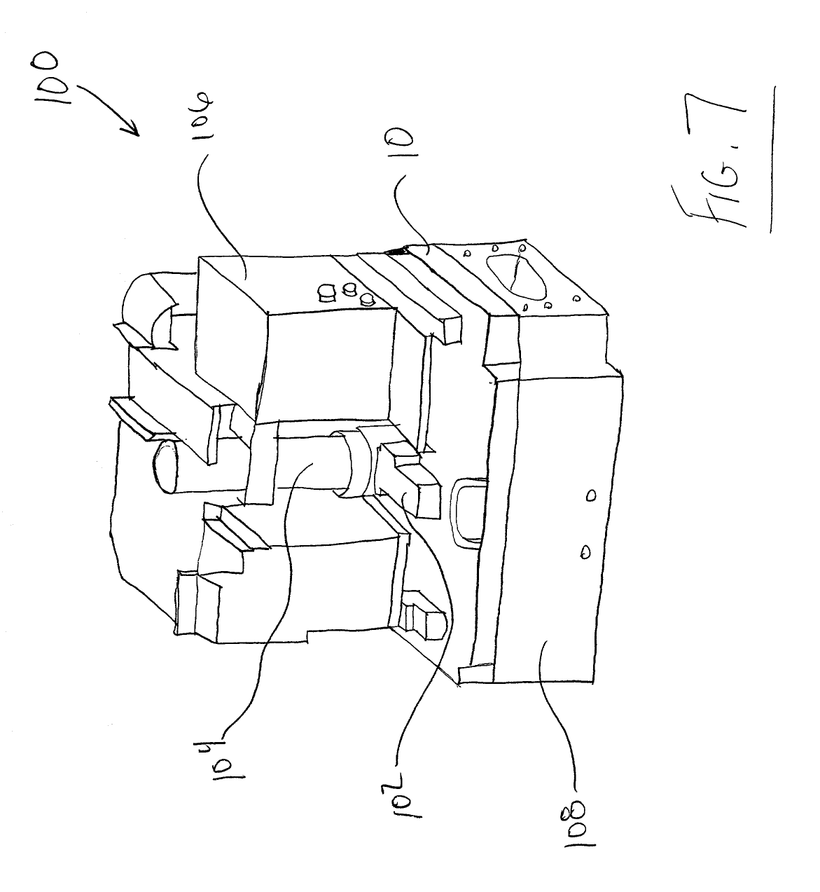

In some embodiments, lid assemblies of the present invention may be used in conjunction with the processing chambers described in U.S. Pat. No. 6,079,356 (the '356 patent), U.S. Pat. No. 6,086,677 (the '677 patent), and U.S. Pat. No. 5,906,683 (the '683 patent), all of which are assigned to the assignee of the present invention, and are incorporated herein by reference. For example, lid assembly 10 may be used to replace the base plate 10 and cap 110 shown in FIG. 2 of the '683 patent. Lid assembly 10 also may be used with the chambers described in conjunction with the '356 patent. In one embodiment, lid assembly 10 replaces the gas box plate 160 and cover plate 34 shown in FIG. 8 therein.

FIG. 1C depicts lid assembly 10 in association with a gas dispersion or blocker plate 42 and a gas distribution plate or showerhead 40. In one embodiment, gas distribution and dispersion plates 40, 42 are affixed to a lower surface 45 of lid assembly 10 with a plurality of threaded mounting screws 60, 70, respectively. In one embodiment, lower surface 45 is a surface of bottom plate 16. Mounting screws 60, 70 provide relatively tight, surface-to-surface contact between contact surfaces 47, 49 of gas distribution and dispersion plates 40, 42, respectively, and lower surface 45 of lid assembly 10 to facilitate conductive heat exchange therebetween. In one embodiment, the mounting screws 60, 70 comprise a process compatible material, such as nickel or the like.

Gas distribution plate 40, in one embodiment, is a generally dish-shaped device having a centrally disposed cavity 44 formed by a side wall 46 and a base wall 48. A plurality of gas distribution holes 50 are formed through base wall 48 for distributing process gases therethrough onto a substrate or wafer, such as a semiconductor wafer. The size and arrangement of holes 50 will vary depending on the process characteristics. For example, holes 50 may be uniformly spaced to provide a uniform distribution of gases onto the wafer. On the other hand, holes 50 may be non-uniformly spaced and arranged, if desired. In one embodiment, holes 50 have a diameter in the range of about 0.005 mm to about 0.1 mm, and in another embodiment, in the range of about 0.02 mm to about 0.04 mm. As shown in FIG. 1C, plate 40 further includes an annular flange 52 projecting outwardly in a horizontal plane from the upper portion of plate 40. Flange 52 includes a plurality of holes 53 for receiving mounting screws 60 to provide engagement of contact surface 47 of plate 40 with lower surface 45 of lid assembly 10.

Gas dispersion plate 42 is generally a circular disk defining a recess 72 for allowing gas passing through lid assembly 10 to disperse between lower surface 45 of lid assembly 10 and gas dispersion plate 42. Dispersion plate 42 further includes a plurality of gas dispersion holes 74 in communication with recess 72 for dispersing the gas therethrough into cavity 44 of gas distribution plate 40. In one embodiment, dispersion holes 74 have a diameter of about 0.02 mm to about 0.04 mm. Of course, it will be recognized by those skilled in the art that dispersion plate 42 may not be necessary for practicing the invention. The process gases may be passed directly from lid assembly 10 into cavity 44 of gas distribution plate 40, if desired.

Turning now to FIGS. 2-6, additional details of lid assemblies 10 according to some embodiments of the present invention will be described.

FIG. 2 depicts an exploded cross-sectional view of the upper, middle and lower components 12, 14, and 16 which form one embodiment of lid assembly 10. In one embodiment, lid assembly 10 is formed using a fusing or vacuum brazing process. To fabricate lid assembly 10, the lower, middle and upper plates 12, 14, and 16 have their mating surfaces coated with a film 18, such as a silicon-rich aluminum film 18. The entire assembly is clamped or otherwise held together, and placed in a furnace at elevated temperatures. In one embodiment, a temperature of approximately 550 degrees Celsius is used to braze (fuse) the component contacting surfaces to one another. In this manner, a unitary lid assembly 10 is formed. As such, no O-rings are necessary to maintain a separation between the process gases that flow through channels in lid assembly 10. In this manner, all three components 12 14, and 16 are fused or brazed together simultaneously.

In another embodiment, two of the three components 12, 14 and 16 are first fused or brazed together as described above. Then, a similar process is used to fuse the two now-joined components to the third component of lid assembly 10.

In one embodiment, each component 12, 14 and 16 comprises a metal. In some embodiments, one or more of the components comprise aluminum, nickel, and the like. In one particular embodiment, Al-6061T6 is the aluminum used for one, two, or all three components. It will be appreciated by those skilled in the art that other materials, such as ceramics, other metals, and other aluminum alloys may be used within the scope of the present invention.

In one embodiment, components 12, 14 and 16 comprise a ceramic. In such an embodiment, components 12, 14 and 16 may be coupled together by metalizing the mating surfaces and brazing or fusing the components as described herein. Alternatively, ceramic components 12, 14 and 16 may be pressure bonded to fuse components 12, 14 and 16 together.

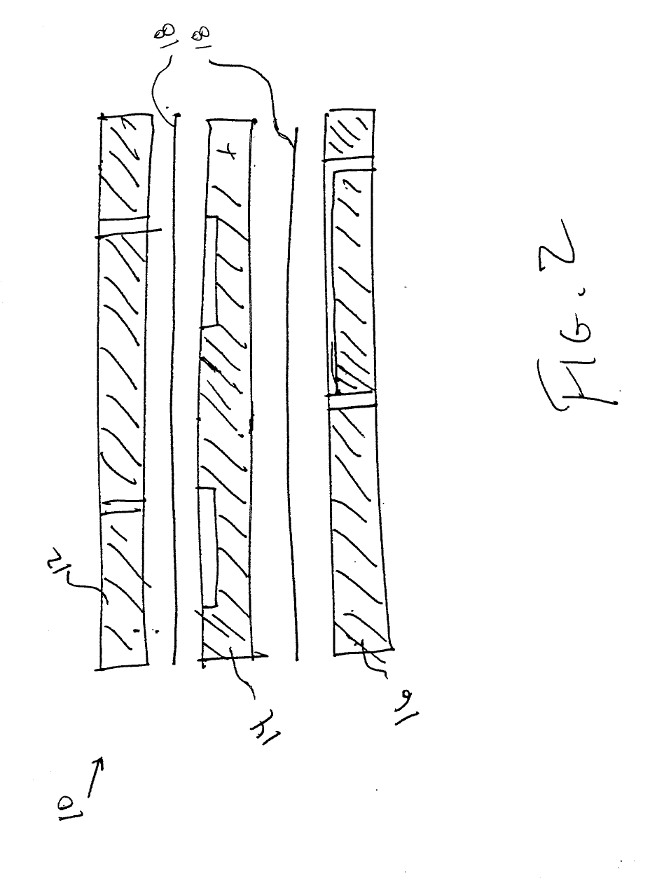

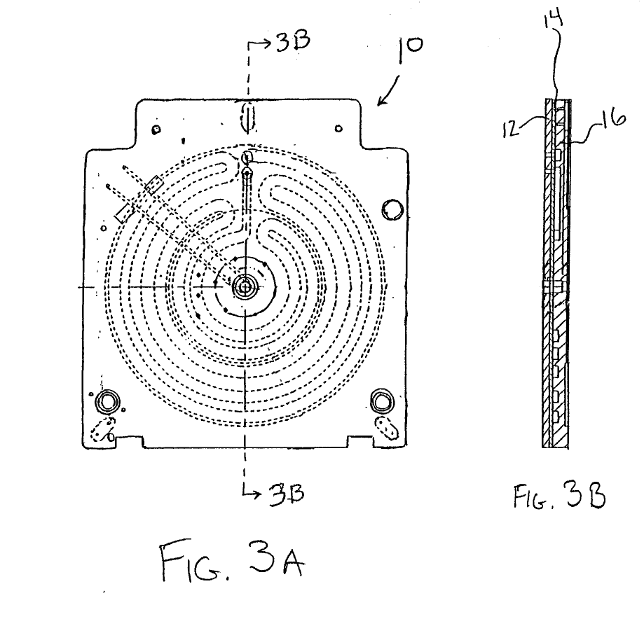

FIGS. 3A and 3B show the three components 12, 14 and 16 fused together into lid assembly 10. Lid assembly 10 is an integral, single-piece element that functions to deliver process gas(es) to gas dispersion plate 42 and to mount to the mainframe unit of the processing chamber. The compact nature of lid assembly 10 provides additional benefits as described below. Additional details on components 12, 14 and 16, shown prior to lid assembly 10 formation, are provided below in FIGS. 4A-4C, 5A-5C and 6A-6C, respectively.

As shown in FIGS. 4A-4C, bottom plate 16 includes a coolant passage 110 formed in an upper surface 112 of plate 16. A lower surface 114 of plate 16 is adapted to be coupled to and seal a processing chamber opening. In one embodiment, surface 114 is surface 45 as discussed in conjunction with FIG. 1C, with surface 114 coupled to blocker plate 42 and/or showerhead 40. Plate 16 has a central hole 116 passing therethrough. Hole 116 is in communication with gas channel(s) formed in middle plate 14 and/or upper plate 12. Hole 116 also is in communication with recess 72 of the gas dispersion plate 40 for dispersing the gas across plate 40 to holes 74.

As best shown in FIG. 4A, coolant passage 110 preferably comprises a plurality of substantially annular channels 120 connected with each other to form a single, continuous fluid passage through lid assembly 10. In one embodiment, passage 110 comprises between about two (2) to about thirty (30) channels 120, and more preferably, between about three (3) to about eight (8) channels 120. Coolant passage 110 has an inlet 122 and an outlet 124. Alternatively, inlet 122 and outlet 124 may be reversed, so that inlet 122 is the outlet and outlet 124 is the inlet. Inlet 122 and outlet 124 are preferably coupled to a coolant source, and are respectively configured to receive the coolant, such as a liquid coolant, from the coolant source and to discharge the spent coolant. Coolant fluid flows through channels 120, and operates to convectively cool portions of lid assembly 10.

Inlet 122 and outlet 124 preferably are positioned at opposing ends of passage 110, and are accessible by way of ports through the uppermost lid assembly component 12. Alternatively, ports may be located through lower surface 114, or along an outer edge of bottom plate 16, middle plate 14 and/or upper plate 12 to provide an inlet and an outlet for fluid to be passed through coolant channels 120.

In one embodiment, passage 110 has a serpentine configuration that compels the coolant fluid to flow back and forth through coolant channels 120 in opposite directions around plate 16. The coolant will also flow radially inward as it passes between each channel 120. Alternatively, depending on the positioning of inlet 122 and outlet 124, coolant may flow radially outward as it passes between each channel 120.

Channels 120 are radially spaced from each other across plate 16 to form a substantially large, heat-exchanging surface area between the coolant flowing therethrough and plate 16. Preferably, channels 120 also are configured to increase the convective cooling of the portions of plate 16 adjacent to or close to mounting screws 60, 70. This facilitates conductive cooling through contact surfaces 47, 49 of dispersion and distribution plates 42, 40 and plate 16.

In one embodiment, the cross-sectional area of channels 120 is generally constant throughout passage 110. In an alternative embodiment, the cross-sectional area of channels 120 become larger as they move radially inward so that the coolant will flow fastest around the outermost channel 120 and will begin to slow as it passes through the inner channels 120. This configuration increases the rate of convective cooling to plate 16 around mounting screws 60, 70. In one particular embodiment, the cross-sectional area of the outermost channel 120 is between about 0.03 mm² to about 0.04 mm² and the cross-sectional area of the innermost channel 120 is between about 0.04 mm² to about 0.05 mm². It will be appreciated by those skilled in the art that different size channels also may be used within the scope of the present invention.

In an alternative embodiment, it is desirable to heat lid assembly 10 to a desired temperature or temperature range. In this embodiment, a heated fluid source is coupled to inlet 122, and a heating fluid is flowed through passage 110 and channels 120.

In still another embodiment, lid assembly 10 has two separate passages 110 formed therein. In this embodiment, the two passages 110 are coupled to two fluid sources to provide the option of having fluids with different temperatures pass through channels 120. In a particular variation of this embodiment, one fluid source is a cooling fluid, and the second fluid source is a heating fluid, in order to provide the lid assembly 10 to operate at two temperatures. It will be appreciated by those skilled in the art that a different number of fluid sources and/or passages 110 also may be used within the scope of the present invention, to provide, if needed, greater than two different temperatures or two different types of cooling/heating fluids.

Additional details on coolant and/or heating channels and passageways are disclosed in U.S. Pat. No. 5,906,683, the complete disclosure of which has been previously incorporated herein by reference. It should be understood that the present invention is not limited to the configuration described above and illustrated in FIGS. 4A-4C. For example, passage 110 may comprise a number of separate, isolated fluid channels rather than a single, continuous passage. Further, passage 110 may have a different configuration than the serpentine pattern depicted in FIG. 4A.

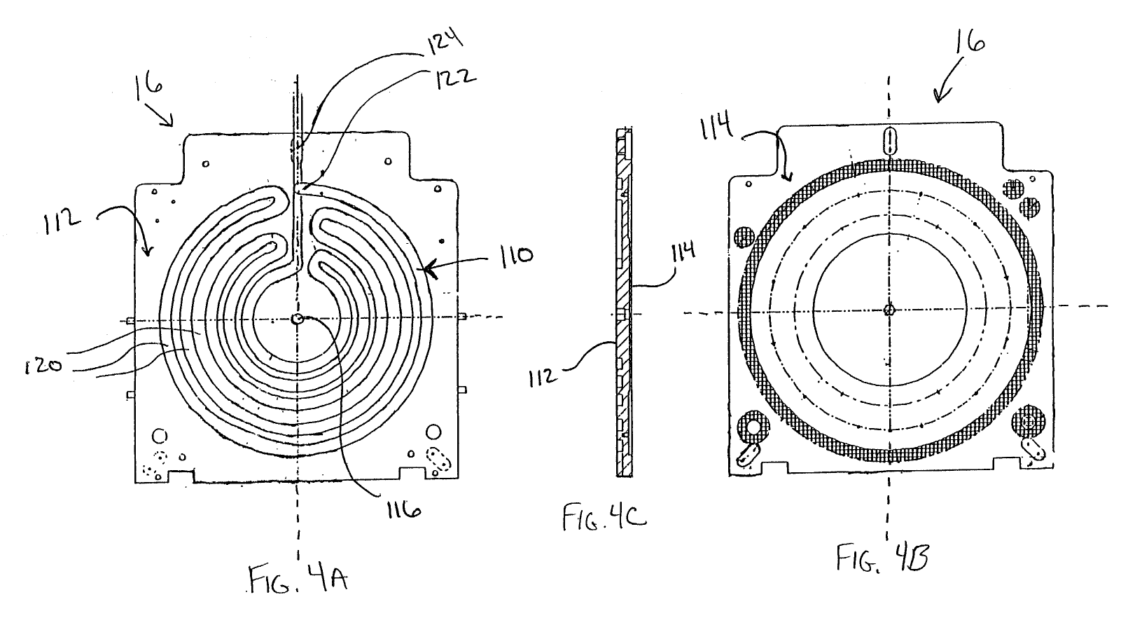

FIG. 5A-5C depicts middle component or plate 14 of lid assembly 10. Plate 14 has an upper surface 140 and a lower surface 142, with lower surface 142 mated to surface 112 of plate 16 by brazing, fusing or the like. By mating surfaces 142 and surface 112, lower surface 142 defines a portion of passage 110, and passage 110 is fluidly sealed without the need for O-rings or other sealing devices. Lower surface 142, in one embodiment, is a generally flat or substantially smooth surface 142. In this embodiment, passage 110 has a generally flat surface on one side. In a particular embodiment, passage 110 has a generally semi-circular cross section resulting from the generally smooth surface 142. In an alternative embodiment (not shown in FIG. 5B), lower surface 142 has a passage formed therein that is substantially the mirror image of passage 110. In this manner, the passage in lower surface 142 and passage 110 together define the coolant channels when surfaces 142 and 112 are fused together. In one such embodiment, the coolant channels have a generally circular cross section.

As best shown in FIG. 5A, upper surface 140 of plate 14 has first and second gas channels 146, 148 formed therein. Channels 146 and 148 have, in one embodiment, a semi-circular cross section within surface 140. It will be appreciated by those skilled in the art that channels 146 and 148 also may have other shapes within the scope of the present invention, including having cross sections that are square, triangular, rectangular, elliptical and a variety of other geometric or irregular shapes.

Channels 146 and 148 each have an inlet, 150 and 152, respectively. Inlets 150 and 152 are preferably coupled to one or more gas sources to facilitate the delivery of process and/or inert gases to the substrate processing chamber. Channels 146 and 148 are spaced apart, except in one embodiment channels 146 and 148 each have an outlet or end point that is co-located with a hole 144 in plate 14. Hole 144 passes through plate 14, and is aligned with hole 116 in plate 16. In this manner, gases introduced into inlets 150 and 152 pass through channels 146 and 148, respectively, and proceed through hole 144. The gases then continue through hole 116 in plate 16, and on into recess 72 of the gas dispersion plate 40. As a result, gases can be introduced into the processing chamber using lid assembly 10 of the present invention.

It will be appreciated by those skilled in the art that variations of plate 14 are within the scope of the present invention. For example, while FIG. 5A depicts plate 14 having two gas channels 146 and 148, plate 14 also may have a single gas channel, or more than two gas channels within the scope of the present invention. Further, channel outlets, while co-located in FIG. 5A, can be separate. In such an embodiment, channels 146 and 148 would each be coupled to a separate outlet, which then can be coupled to hole 144 and/or hole 116 to deliver gases therethrough. In another embodiment, channels 146 and 148 have separate outlets that pass through plate 16 and into recess 72 or directly into a process chamber to provide for exemplary gas distribution therein.

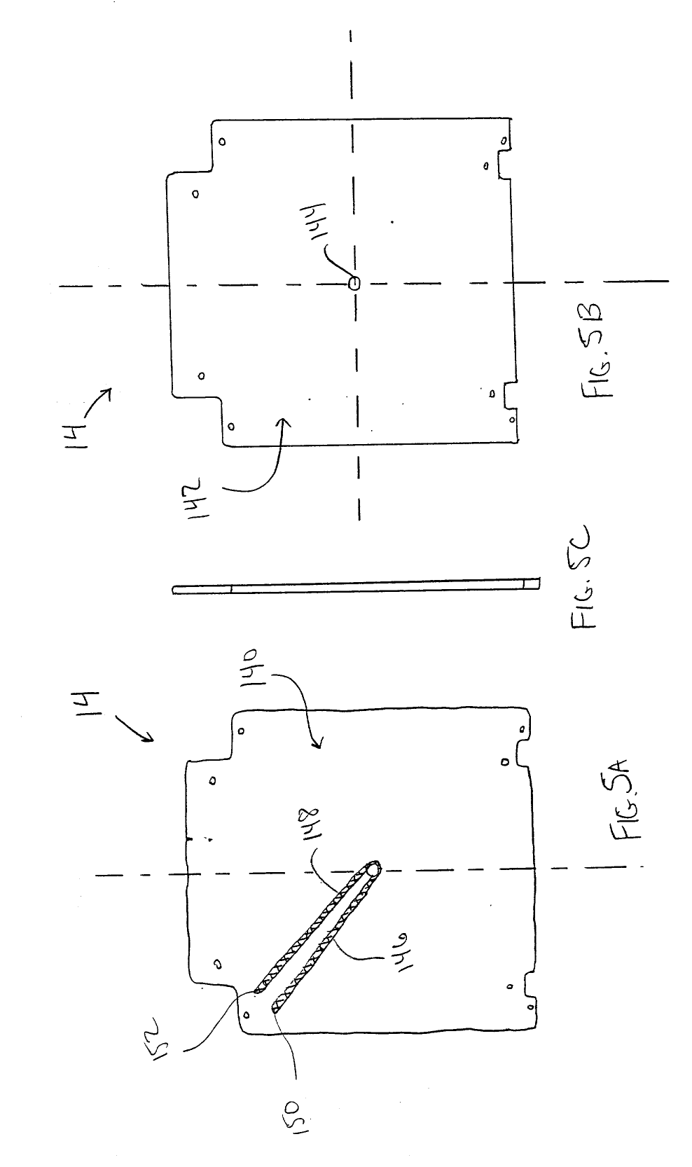

Turning now to FIGS. 6A-6C, top plate 12 having an upper surface 160 and a lower surface 162 will be described. As shown, lower surface 162 has two gas channels 164 and 166 formed therein. Channels 164 and 166 are substantially mirror images of channels 146 and 148 in plate 14. In this manner, when plates 14 and 12 are fused or brazed together, and more specifically when surface 140 is mated with surface 162, channels 164 and 148 together define a first gas channel and channels 166 and 146 together define a second gas channel. The cross sections of the resultant gas channels formed in and between plates 12 and 14 will depend upon the cross sections of the two opposing channels, such as channels 166 and 146. In one embodiment, channel 146 and channel 166 each have an approximately semi-circular cross section so that when plates 12 and 14 are mated, the resulting gas channel has a substantially circular cross section. Similar relationships exist, in one embodiment, for channels 164 and 148.

As shown in FIG. 6B, channels 164 and 166 each have an inlet 172 and 174, respectively. Channels 164 and 166 each have an outlet which, in one embodiment, are co-located with a hole 168. In one embodiment, hole 168 is aligned with hole 144 and hole 116, so that gases introduced in channels 164 and 166 pass through lid assembly 10 into the substrate processing chamber.

Upper surface 160 of plate 12 is, in one embodiment, substantially smooth or planar. Surface 160 has a cap 170, which plugs hole 168. In this manner, gases introduced into channels 164 and 166 pass through hole 168 into the processing chamber, but cannot exit the top of lid assembly 10 due to cap 170. In one embodiment, cap 170 is a portion of plate 12 or is integrally formed with plate 12 so as to not be removable. In an alternative embodiment, cap 170 can be removed, such as to facilitate cleaning of holes 116, 144 and 168 and/or channels 146, 148, 164 and 166.

By fusing top plate 12 with middle plate 14 as described, process and/or inert gas(es) may pass through lid 10 efficiently. The gas channels formed therein help keep the gases separate until their combination is desired. Further, by brazing or fusing plates 10, 12 and 14 together, O-rings and other sealing mechanisms are not needed to prevent leaks of gases or coolant fluids.

One advantage of the present invention is that by forming gas channels 164, 166, 146 and 148 within lid assembly 10, a gas manifold, such as manifold 14 as shown in FIG. 5 of the '683 patent, is not needed. As a result, other components, such as a microwave generation device or remote plasma clean assembly, can be positioned on top of lid assembly 10 and hence closer to the process chamber. In this manner, improved plasma clean characteristics can be achieved. Improved cleaning results, at least in part, since the dissociated radicals reach the surface to be cleaned faster, and hence without losing their effectiveness based on the life of the species, and/or without recombining before cleaning can occur.

FIG. 7 depicts a simplified view of a substrate processing apparatus 100 and related components according to the present invention. As shown, processing apparatus 100 includes lid assembly 10 according to the present invention coupled to a process chamber 108. A gate valve 102, such as a VAT™ gate valve 102 is provided and is coupled to an applicator 104. Gate valve 102 also is coupled to a microwave generator 106, such as a Daihen™ microwave, or other microwave apparatus. VAT valve 102 provides for the opening and closing of the microwave line having a large aperture. Daihen microwaves 106 can be obtained from Daihen Advanced Components, Inc. in Santa Clara, Calif. These microwaves provide for the creation of a plasma with recommended power and pressure environments inside the cavity to dissociate NF₃, thereby creating Fₓ and F₂ for etching tungsten (W) deposits inside the chamber and on the process kits.

In one embodiment, NF₃ passes through a sapphire tube inside generator 106. Radical Fₓ species are generated therein, and are introduced into chamber 108 by passing through gate valve 102, and possibly plate 42 and plate 40 as shown in FIG. 1C. Alternatively, a remote plasma generating module is used. Gate valve 102 directs Fₓ species to chamber 108, and is typically open during cleaning, and closed during processing operations. Gate valve 102 is used to provide a bigger opening and better conductance, for faster cleaning. In one embodiment, the components inside are aluminum, so Fₓ radicals will not attack the components. In an alternative embodiment discussed further below, multiple inlets through lid assembly 10 can result in multiple locations for injecting Fₓ radicals into chamber 108 during cleaning operations. Such an embodiment provides for effective and generally uniform cleaning.

Turning now to FIG. 8, an alternative embodiment 200 of the present invention will be described. Embodiment 200 includes a lid assembly 210 similar to that described in conjunction with FIGS. 1-7. Lid assembly 210 includes an upper plate 212 and a bottom or lower plate 216, both coupled to opposing surfaces of a middle plate 214. As with earlier discussed embodiments, plates 212, 214 and 216 may be a variety of materials, including metal such as aluminum. In one embodiment, plates 212, 214 and 216 are vacuum brazed or fused together as previously described. As shown in the embodiment of FIG. 8, first plate 212 includes a plurality of cooling channels 222 similar to those described in connection with FIG. 4A. Cooling channels 222 are coupled to a coolant source, and a reservoir or other device to receive the spent coolant. As shown, plate 212 has a generally flat upper surface so that a microwave generator (not shown) or other device may be coupled thereto.

Middle plate 214 has a substantially smooth upper surface that is coupled to plate 212 to partially define coolant channels 222. The opposing surface of middle plate 214 has one or more gas distribution channels 230, similar to those described in conjunction with FIGS. 5A and 6B. Gas distribution channels 230 are coupled to one or more gas sources to deliver process and/or inert gases to a substrate processing chamber.

A third plate 216 includes a plurality of passages 232 extending between spaced apart first and second surfaces of plate 216. As shown in FIG. 8, in one embodiment, the second surface of plate 216 is coupled to a blocker plate 242 and a showerhead 240. Passages 232 connect gas distribution channels 230 with blocker plate 242, and further may couple the gas distribution channels 230 with a cavity such as cavity 44 shown in FIG. 1C. In such an embodiment, one or more gases may be injected into a process chamber to provide exemplary gas mixing prior to deposition on the substrate or wafer. In this manner, improved deposition uniformity can be achieved.

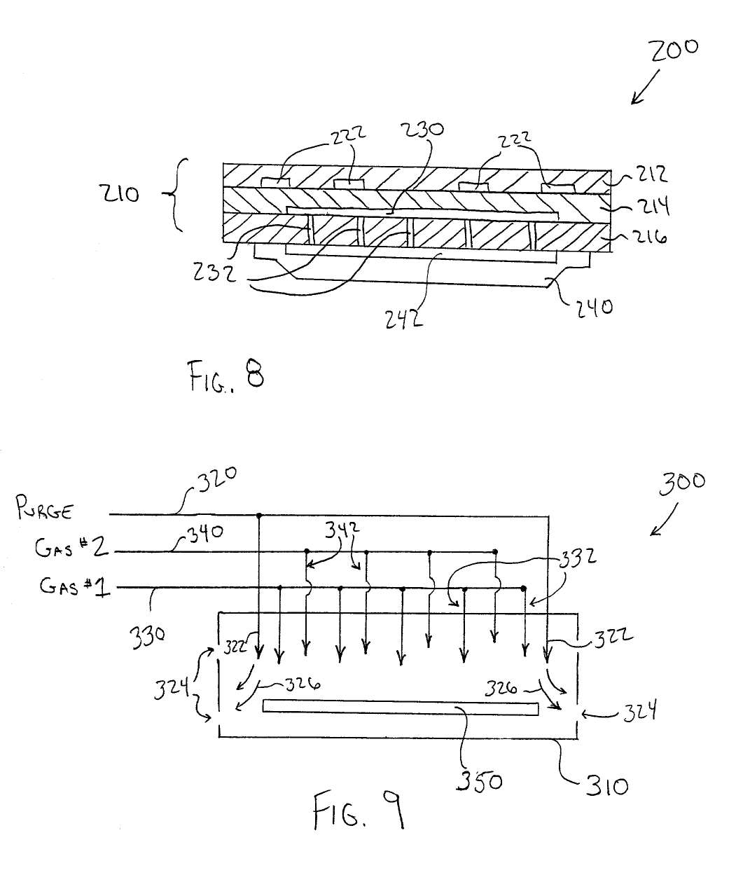

FIG. 9 is a simplified process schematic depicting the distribution of process gases and purge gases into a process chamber according to one embodiment of the present invention. In this embodiment 300, a wafer 350, such as a semiconductor wafer 350, is maintained in a process chamber 310. Process chamber 310 may be a wide range of process chambers within the scope of the present invention, including chambers for the chemical vapor deposition (CVD) of process gases, atomic layer deposition (ALD) and the like. Wafer 350 may be held by a susceptor or platen (not shown) within chamber 310.

Lid assemblies of the present invention, such as lid assembly 210, are used to provide exemplary gas distribution into chamber 310. As shown in FIG. 9, a first gas is injected into chamber 310 using a plurality of injection points or ports. The gas injection ports, in one embodiment, correspond to passages 232 formed in lid assembly 210. The positioning of passages 232 are designed to achieve the proper mixing and gas distribution. In this manner, improved uniformity of gas distribution onto wafer 350 may be achieved.

As shown in FIG. 9, a second gas may be introduced between and/or around first gas to obtain proper mixing of first and second gases before deposition or other processes related to wafer 350. Gas mixing may occur in chamber 310, with the gases passing through lid assembly 210 unmixed, and/or within lid assembly 210. As shown in FIG. 9, first gas has a first gas distribution line 330 which couples to a plurality of spaced apart gas passages, shown schematically as arrows 332. Similarly, second gas has a second gas distribution line 340 coupled to one or more gas passages, shown schematically as arrows 342. In one particular embodiment, gas distribution lines 330 and 340 correspond to gas channels 230 shown in FIG. 8, and gas passages referred to by arrows 332 and 342 correspond to passages 232 shown in FIG. 8.

In a particular embodiment, it is desirable to have purge gases introduced about the periphery of chamber 310, and hence about the periphery of wafer 350 during deposition processes. The use of purge gases around the outer periphery will reduce or prevent the deposition of process gases on process kits around the wafer, on chamber 310 walls, and other exposed hardware. By reducing or eliminating unwanted deposition on chamber 310 components, faster clean times for chamber 310 can be achieved.

As shown, in one embodiment purge gases are introduced by a purge gas distribution line 320 to ports positioned about the periphery of wafer 350 and/or chamber walls 310. This arrangement is shown schematically by arrows 322. Again, in a particular embodiment, ports coupled to purge gas distribution line 320 correspond to gas distribution channel 230 and/or one or more passages 232. Process gases and purge gases exit chamber 310 through one or more exhaust ports, shown schematically as ports 324.

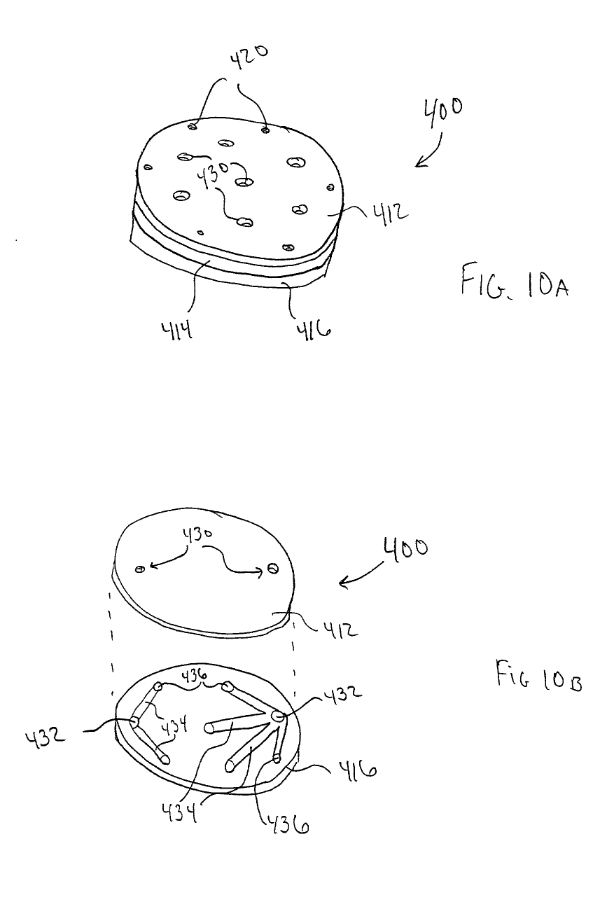

Turning now to FIG. 10A, a particular embodiment of a lid assembly 400 according to the present invention will be described. Lid assembly 400 includes a first plate 412, a second plate 414 and a third plate 416, similar to lid assemblies described in conjunction with prior figures. In one embodiment, first plate 412 has a first plurality of ports 430 and a second plurality of ports 420. In one embodiment, ports 420 are positioned generally about the periphery of plate 412, and are coupled to one or more gas sources, such as an inert or purge gas. In this embodiment, ports 420 pass through plates 412, 414 and 416, thereby providing purge gases into a substrate process chamber, such as chamber 310 shown in FIG. 9. In one embodiment, ports 420 correspond with arrows 322 shown in FIG. 9. In one embodiment, coolant channels, such as channels 222 shown in FIG. 8, may be formed in the coupled surfaces of plate 412 and 414. As with prior embodiments, coolant channels may be formed in mated surfaces of both plates 412 and 414, or in just one of the two mated surfaces.

In one embodiment, ports 430 also pass through plates 412, 414 and 416. In this embodiment, ports 430 correspond generally to arrows 332 and 342 shown in FIG. 9. Ports 430 may be coupled to one or more gas sources for the delivery of process or inert gases to a substrate process chamber. In one embodiment, the number of ports 420 and 430 correspond to the number of injection ports desired for injecting inert and process gases into chamber 310.

Turning now to FIG. 10B, an alternative embodiment of lid assembly 400 will be described. In this embodiment, plate 412 has fewer gas ports 430 than shown in FIG. 10A. Although FIG. 10B depicts two spaced ports 430, a larger or smaller number of ports 430 may be used, and the locations of ports 430 also may vary from that shown, all within the scope of the present invention. In this embodiment, ports 430 pass through plate 412, pass through plate 414 (not shown in FIG. 10B) and into, but not directly through plate 416. Ports 430 are generally aligned with inlet ports 432 formed in plate 416. Inlet ports 432 then direct the process or inert gases along one or more channels 434 to a series of outlet or injection ports 436. Injection ports 436 pass through plate 416 and are configured to deliver the process or inert gases to chamber 310 and/or to showerhead 240 shown in FIGS. 9 and 8, respectively. Preferably, injection ports 436 are positioned about plate 416 to provide the desired distribution of process gases into chamber 310.

FIG. 10B depicts two of a wide variety of channel configurations within the scope of the present invention. As shown, channels 434 properly distribute gases about plate 416 and into chamber 310. For example, inlet port 432 on the left hand portion of FIG. 10B is coupled to two channels 434, which in turn are coupled to two injection ports 436. Inlet port 432 on the right hand portion of FIG. 10B is coupled to four channels 434 and in turn to four injection ports 436.

It will be appreciated by those skilled in the art that a wide range of combinations of channels 434, ports 430 and injection ports 436 may be used within the scope of the present invention. For example, channels 434 and injection ports 436 need not be in a 1:1 ratio. Further, ports 430 formed in plate 412 may be formed closer to one another than depicted in FIG. 10B. Such an embodiment would likely rely on channels 434 in plate 416 to properly distribute the process gases prior to the gases passing through plate 416 and into chamber 310. By placing ports 430 adjacent one another and near the periphery of plate 412, a microwave generation device or other hardware may be mounted to the generally flat upper surface of plate 412 without blocking access to ports 430. Alternatively, ports 430 may be formed in a peripheral edge of lid assembly 200, such as in an edge of plate 412.

While not shown in FIG. 10B, in one embodiment a second or middle plate 414 is formed between plates 412 and 416. Plate 414 would have passages formed therethrough that correspond with ports 430 and 432, to permit passage of the process or inert gases through plate 414 and into inlet ports 432. A lower surface of plate 414 would couple to and fluidly seal channels 434. Similarly, an upper surface of plate 414 and/or a lower surface of plate 412 has a plurality of coolant channels formed therein, as previously described.

While the embodiment shown in FIG. 8 depicts lid assembly 200 coupled to blocker plate 242 and showerhead 240, in one embodiment lid assemblies of the present invention are used without blocker plates 242 or showerheads 240. In this manner, passages 232 are configured to provide the desired distribution of process gases into chamber 310 without the need for a blocker plate and/or a showerhead.

The invention has now been described in detail for purposes of clarity and understanding. However, it will be appreciated that certain changes and modifications may be practiced within the scope of the appended claims. For example, while FIGS. 1-6C generally discuss a lid assembly 10 having plate 16, and hence cooling channels 120, closer to the process chamber than gas channels in plate(s) 12 and 14, this need not be the case. In an alternative embodiment, plate 16 is the upper or top plate, and the gas channels in plate(s) 12 and 14 are closer to the process chamber and/or showerhead than are the cooling channels 120 or passage 110.

What is claimed is:

1. A lid assembly for a semiconductor process chamber of the type having an enclosure defining a processing chamber and an opening, said lid assembly comprising:
a first plate having first and second spaced apart surfaces defining a thickness therebetween, said second surface having a channel formed therein, said channel coupled to an inlet and an outlet;
a second plate coupled to said second surface; and
a third plate having a first channel formed therein, said first channel coupled to a first channel inlet and a first channel outlet, and said third plate coupled to said second plate to fluidly seal said first channel.

2. The lid assembly as in claim 1 wherein said coupled first and second plate fluidly seal said second surface channel.

3. The lid assembly as in claim 1 wherein said second surface channel inlet is coupled to a fluid source.

4. The lid assembly as in claim 1 wherein said first and second plates each have a hole passing therethrough, said holes aligned with one another and aligned with said third plate first channel outlet.

5. The lid assembly as in claim 1 wherein said first channel is coupled to a first gas source.

6. The lid assembly as in claim 1 wherein said third plate further comprises a second channel formed therein, said second channel spaced apart from said first channel.

7. The lid assembly as in claim 6 wherein said second channel further comprises a second channel inlet and a second channel outlet, said second channel outlet coupled to said first channel outlet.

8. The lid assembly as in claim 6 wherein said second channel is coupled to a second gas source.

9. The lid assembly as in claim 1 wherein said first, second and third plates are fused together.

10. The lid assembly as in claim 1 wherein said first, second and third plates comprise aluminum.

11. The lid assembly as in claim 1 wherein said second plate comprises third and fourth surfaces, said third surface having a channel formed therein, said third surface coupled to said second surface so that said channels formed therein collectively define a fixed tube.

12. The lid assembly as in claim 11 wherein said fixed tube is fluidly sealed except for said inlet and said outlet.

13. The lid assembly as in claim 1 wherein said second plate comprises third and fourth surfaces, said fourth surface having a channel formed therein, said fourth surface coupled to said third plate so that said first channel and said fourth surface channel collectively define a fixed tube.

14. The lid assembly as in claim 13 wherein said fixed tube is fluidly sealed except for said first channel inlet and said first channel outlet.

15. The lid assembly as in claim 1 further comprising a gas dispersion plate removably coupled to said first surface.

16. The lid assembly as in claim 1 further comprising a gas distribution plate removably coupled to said first surface.

17. The lid assembly as in claim 1 wherein said second surface channel comprises a serpentine channel.

18. The lid assembly as in claim 1 further comprising a microwave generator removably coupled to said third plate.

19. The lid assembly as in claim 1 further comprising a remote plasma clean unit coupled to said third plate.

20. An integral lid assembly for sealing a substrate processing chamber, said lid assembly comprising:
first and third plates fixedly coupled to a second plate positioned therebetween;
wherein said first and second plates define a fluid channel therein, and said second and third plates define a gas delivery channel therein;
said first plate having a substantially planar surface for coupling to said processing chamber; and
said third plate having a substantially planar surface.

21. The lid assembly as in claim 20 wherein said first and third plates are fused with said second plate positioned therebetween.

22. An integral lid assembly for sealing a substrate processing chamber opening, said lid assembly comprising:
a multi-layer brazed plate formed of two or more individual plates;
said brazed plate having a substantially planar upper surface and a substantially planar lower surface;
said brazed plate having a fluid channel and a gas channel each formed in opposing mated surfaces of said individual plates.

23. The lid assembly as in claim 22 wherein said gas channel is formed in a first plate surface, said first plate surface mated to a generally planar portion of a second plate surface.

24. The lid assembly as in claim 23 wherein said gas channel has a generally semi-circular cross-section.

25. The lid assembly as in claim 22 wherein a first portion of said gas channel is formed in a first plate surface, and a second portion of said gas channel is formed in a second plate surface, said first and second surfaces mated to overlay said first and second portions to define said gas channel.

26. A substrate processing chamber, comprising:
an enclosure defining a chamber and having an opening; and
a lid assembly coupled to said opening, said lid assembly comprising;
first and third plates fixedly fused to a second plate positioned therebetween;
wherein said first and second plates define a fluid channel therein, and said second and third plates define a gas delivery channel therein;
said first plate having a substantially planar surface for coupling to said processing chamber; and
said third plate having a substantially planar upper surface.

27. The substrate process chamber as in claim 26 further comprising a microwave generator mounted to said third plate substantially planar upper surface.

28. The substrate process chamber as in claim 26 further comprising a remote plasma clean assembly mounted to said third plate substantially planar upper surface.

29. The substrate processing chamber as in claim 26 further comprising a gas distribution plate removably mounted to said first plate substantially planar surface, said gas distribution plate defining one or more gas distribution holes formed therethrough to communicate with said chamber.

30. A substrate processing chamber lid assembly, comprising:
a multi-layer brazed plate formed of two or more individual plates, said brazed plate having;
a plurality of spaced apart gas injection ports configured to deliver gases to a processing chamber;
a plurality of gas channels, each of said gas channels coupled to at least one of said injection ports; and
a channel formed therein and configured to be coupled to a fluid source.

31. The lid assembly as in claim 30 wherein said gas injection ports are spaced about a surface of said brazed plate in a configuration designed to distribute gases therefrom in a desired pattern.

32. The lid assembly as in claim 30 wherein at least one of said gas channels is coupled to a purge gas source, and at least another one of said gas channels is coupled to a process gas source.

33. The lid assembly as in claim 30 wherein said fluid source comprises a heating fluid source.

34. The lid assembly as in claim 30 wherein said fluid source comprises a cooling fluid source
